(19) United States
(12) Patent Application Publication
(10) Pub. No.: US 2008/0077836 A1
(43) Pub. Date: Mar. 27, 2008

(54) Diagnostic Information Capture from Memory Devices with Built-in Self Test

(76) Inventors: A. Jay Khoche, San Jose, CA (US); Klaus-Dieter Hilliges, Shanghai (CN)

Correspondence Address: VERIGY, 4700 INNOVATION WAY, BLDG D1, FORT COLLINS, CO, 80528, US

(21) Appl. No.: 11/535,974

(22) Filed: Sep. 27, 2006

(51) Int. Cl. G01R 31/28

(52) U.S. Cl. 714/733

(57) ABSTRACT

From a memory device comprising a built-in self-test system (BIST), diagnostic information is obtained by using the BIST to write a test pattern at a memory location in the memory device and to read a respective output pattern from the memory location; comparing the output pattern with a corresponding expected pattern identical to the test pattern, the comparing providing a fault indication when the output pattern differs from the expected pattern; temporarily storing a diagnostic pattern corresponding to the output pattern such that diagnostic patterns corresponding to no more than a most-recently read subset of output patterns are stored; and outputting at least some of the stored diagnostic patterns in response to the comparing providing the fault indication. The most-recently read subset out put patterns consists of output patterns read from fewer than all the memory locations in the memory device.

### RELATED APPLICATIONS

This disclosure is related to the following U.S. patent applications filed on the filing date of this disclosure: Ser. No. ______ of Khoche et al. entitled Diagnostic Information Capture from Logic Devices with Built-in Self Test (Docket no. 10051609) and Ser. No. ______ of Khoche et al. entitled Automatic Test Equipment Receiving Diagnostic Information from Devices with Built-in Self Test (Docket no. 10060524). The above disclosures are assigned to the assignee of this disclosure and are incorporated herein by reference.

### BACKGROUND

The ever-increasing complexity of integrated circuits, especially memory devices, i.e., integrated circuits that comprise memory circuits, has led to memory devices being designed with a built-in self-test system (BIST) to facilitate testing during manufacture. Automatic test equipment (ATE) is still used to test the memory device, but the automatic test equipment simply controls the BIST and evaluates a test result generated by the BIST.

A memory device that incorporates a built-in self test system typically comprises a memory circuit and a BIST. The BIST comprises a data generator, an address generator and a control signal generator that respectively provide test patterns and expected patterns, address data and control signals via respective multiplexers to the data inputs, address inputs and control inputs of the memory circuit. The test patterns are written at memory locations in the memory circuit and respective output patterns are then read from the memory locations. Each output pattern is compared with a corresponding expected pattern identical to the test pattern that was written at the memory location from which the output pattern was read to determine whether a difference exists. Differences, if any, detected between the output patterns and the corresponding expected patterns are accumulated in the BIST to generate a cumulative difference. At the end of the test sequence, the cumulative difference is output to the host ATE as the test result for the memory device under test. The ATE evaluates the cumulative difference to determine whether it indicates that the testing has detected a difference between any of the output patterns and its corresponding expected pattern. A difference indicates that the memory device under test is faulty.

Outputting a cumulative difference significantly reduces the volume of communication traffic between the BIST and the host ATE. However, the cumulative difference only allows the ATE to determine whether the memory device under test as a whole has passed or failed the test sequence. The data compression involved in generating the cumulative difference prevents the ATE from identifying the portion of the memory circuit that has caused the device under test to fail the test. Such information is highly desirable, especially to allow process optimization during production ramp-up but also during on-going production to facilitate process control.

FIG. 1A is a block diagram of an example of a memory device under test 10 being tested by automatic test equipment 12. Memory device 10 comprises a memory circuit 14 and a built-in self-test system (BIST) 16. Sellers of commercially-available BISTs include Synopsys, Inc., Mountain View, Calif. and Mentor Graphics Corp., Wilsonville, Oreg.

The example of BIST 16 shown is composed of a pattern generator (PG) 20, an address generator (AG) 24, a control signal generator (CG) 28 and multiplexers 34, 36, and 38. Multiplexers 34, 36, and 38 each have two inputs and an output, and are interposed between the outputs of pattern generator 20, address generator 24 and control signal generator 28, respectively, and the data input (DATA), address input (ADR) and control input (CTRL) of memory circuit 14. Pattern generator 20, address generator 24 and control signal generator 28 are connected to one input of multiplexers 34, 36 and 38, respectively. The functional data input FD, the functional address input FA and the functional control input FC of memory device 10 are connected to the other input of multiplexers 34, 36 and 38, respectively. Functional data input FD, functional address input FA and functional control input FC are the inputs of memory device 10 used for data, address and control signals, respectively, during in-service operation of memory device 10, i.e., during operation of memory device 10 except when it is being tested by BIST 16. During in-service operation of memory device 10, multiplexers 34, 36 and 38 connect the functional data input FD, the functional address input FA and the functional control input FC, respectively, of memory device 10 to the data input (DATA), address input (ADR) and control input (CTRL), respectively, of memory circuit 14.

BIST 16 additionally comprises a difference detector and accumulator (DDA) 22.

Difference detector and accumulator 22 has an output pattern input OP, an expected pattern input EP and a cumulative difference output CD. Output pattern input OP is connected to the read output (RO) of memory circuit 14 to receive the output patterns read from the memory locations of memory circuit 14 defined by the addresses generated by address generator 24 and in response to the control signals generated by control signal generator 28. Expected pattern input EP is connected to the output of pattern generator 20 to receive a corresponding expected pattern corresponding to each output pattern received at output pattern input OP. The corresponding expected pattern is identical to the test pattern written at the memory location of memory circuit 14 from which the output pattern was read. Difference detector and accumulator 22 detects any difference between each output pattern and the corresponding expected pattern and accumulates such difference to generate the above-described cumulative difference. Cumulative difference output CD is connected to ATE 12. At the end of the test sequence performed by BIST 16, difference detector and accumulator 22 outputs the cumulative difference to ATE 12 via cumulative difference output CD.

BIST 16 additionally comprises a BIST controller 26 that communicates with ATE 12 directly or via other logic, such as a JTAG port (not shown). BIST controller 26 controls the operation of difference detector and accumulator 22, pattern generator 20, address generator 24 and control signal generator 28. During operation of BIST 16 to test memory device under test 10, control signals output by BIST controller 26 cause multiplexers 34, 36 and 38 to connect the outputs of pattern generator 20, address generator 24, control signal generator 28, respectively, to the data input (DATA), address input (ADR) and control input (CTRL), respectively, of memory circuit 14. The control signals output by BIST controller 26 additionally cause pattern generator 20, address generator 24 and control signal generator 28 to generate the test patterns and expected patterns, the addresses and the WRITE and READ commands, respectively, used to test memory circuit 14. At the end of the test sequence, a control signal output by BIST controller 26 to a control input C of difference detector and accumulator 22 causes difference detector and accumulator 22 to output the cumulative difference to ATE 12 via its cumulative difference output CD.

FIG. 1B is a flow chart illustrating the operation of BIST 16 described above with reference to FIG. IA to test memory circuit 14 that forms part of memory device 10 under test. Execution begins at block 50. In block 52, BIST controller 26 is initialized. Once initialized, BIST controller 26 generates control signals that cause pattern generator 20, address generator 24 and control signal generator 28 to generate the test patterns and expected patterns, the addresses and the WRITE and READ commands, respectively, used to test memory circuit 14. Typically, the control signals generated by BIST controller 26 cause pattern generator 20, address generator 24 and control signal generator 28 to execute one or more memory test algorithms, e.g., a march algorithm. Examples of march algorithms include MARCH C-, MARCH LR, etc. Other suitable algorithms include Walking One, Walking Zero, Checkerboard, Address Unique, GALPAT, etc. Address generator 24 generates addresses that walk across entire memory circuit 14 and pattern generator 20 generates one or more test patterns that are written at memory locations in memory circuit 14 and additionally generates the corresponding expected patterns that difference detector and accumulator 22 compares with the output patterns read from memory circuit 14. Any difference between the output pattern and the corresponding expected pattern indicates a faulty memory location in memory circuit 14. Control signal generator 28 generates control signals that determine the READ or WRITE mode of memory circuit 14.

In block 54, the test pattern generated by pattern generator 20 is written at a memory location in memory circuit 14 defined by an address generated by address generator 24. In block 56, a respective output pattern is read from the memory location in memory circuit 14 defined by the address generated by address generator 24, i.e., the memory location at which the test pattern was written in block 54.

Typically, in block 54, a single test pattern is written at multiple memory locations in memory circuit 14 and, in block 56, such multiple memory locations are sequentially read to provide respective output patterns. Alternatively, multiple test patterns are written at multiple memory locations in block 54 before the memory locations are sequentially read to provide respective output patterns in block 56.

In block 58, difference detector and accumulator 22 compares the output pattern read from the memory location in block 56 with the corresponding expected pattern generated by pattern generator 20 to detect whether the output pattern differs from the expected pattern. Difference detector and accumulator accumulates any difference detected to generate a cumulative difference.

In block 60, a test is performed to determine whether all the tests in the test sequence have been performed. A NO result returns execution to block 54 so that another test can be performed. A YES result advances execution to block 62.

In block 62, difference detector and accumulator 22 outputs the cumulative difference to ATE 12. Any difference indicated by the cumulative difference indicates that memory device under test 10 is faulty. However, the cumulative difference gives no indication as to the location of the fault(s) in memory device under test 10.

FIG. 1C is a block diagram of an example of the difference detector and accumulator 22 of memory device under test 10. In the example shown, the output pattern read from a memory location in memory circuit 14 and the corresponding expected pattern generated by pattern generator 20 are each N-bit quantities. Difference detector and accumulator 22 is composed of N channels labelled CH₁ to CH_{N}. Each channel receives a respective bit of the output pattern OP and a corresponding bit of the corresponding expected pattern EP, and generates a respective bit of the cumulative difference D.

Each channel of difference detector and accumulator 22 is composed of an exclusive-OR (XOR) gate 71, an OR gate 73 and a flip-flop 75. In channel CH₁, for example, the inputs of XOR gate 71 are connected to receive the first bit OP₁ of the output pattern and the first bit EP₁ of the corresponding expected pattern. The output of XOR gate 71 is connected to one input of OR gate 73. The output of OR gate 73 is connected to the D-input of flip-flop 75. The Q-output of flip-flop 75 is connected to the other input of OR gate 73 and additionally provides the first bit D₁ of the cumulative difference D output by difference detector and accumulator 22. Flip-flop 75 additionally has a clock input and a reset line respectively connected to a clock line and a reset line. Neither the clock line nor the reset line is shown to simplify the drawing. The remaining channels CH₂−CH_{N} of difference detector and accumulator 22 are identical in structure to channel CH₁. The inputs of XOR gate 71 of each channel CH₂-CH_{N} receive a respective bit OP₂−OP_{N} of the output pattern and the corresponding bit EP₂−EP_{N} of the corresponding expected pattern and generate a respective bit D₂−D_{N} of the cumulative difference.

At the start of testing memory device 10, a reset signal on the reset line resets the Q-outputs of flip-flops 75 to a logical 0. After the first test performed on memory device 10, in each channel of difference detector and accumulator 22, the bit of the output pattern and the bit of the corresponding expected pattern are identical provided that the tested memory location is not faulty, as is typical. Consequently, the output of XOR gate 71 remains a logical 0. The logical 0s on both inputs of OR gate 73 cause the output of OR gate 73 to be a logical 0. The next clock pulse applied to the clock input of flip-flop 75 clocks the logical 0 on the D-input to the Q-output. Thus, after each non-faulty memory location of memory device 14 is tested, the respective bit of cumulative difference D output by the channel remains a logical 0.

In an example of memory device 10 in which one or more of the memory locations is faulty, in at least one channel of difference detector and accumulator 22, the bit of the output pattern output by such memory location will differ from the corresponding bit of the corresponding expected pattern. The difference changes the output of the corresponding XOR gate 71 to a logical 1. The logical 1 applied to one input of OR gate 73 changes the output of OR gate 73 to a logical 1. The next clock pulse applied to the clock input of flip-flop 75 clocks the logical 1 on the D-input to the Q-output. Thus, the first time in the test sequence that a bit of the output pattern differs from the corresponding bit of the corresponding expected pattern, the respective bit of cumulative difference output D by the channel changes to a logical 1.

Then, in all tests subsequently performed on the faulty memory device, the logical 1 applied to the input of OR gate 73 by the Q-output of flip-flop 75 holds the output of OR gate 73 and, hence, the D-input of flip-flop 75, at a logical 1 regardless of the result of the test and the consequent state of the output of XOR gate 71. Thus, the bit of the cumulative difference set to a logical 1 by the bit of the output pattern received from the faulty memory location remains as a logical 1 to the end of the test sequence. Other bits of the cumulative difference can be changed to a logical 1 by subsequently-tested faulty memory locations and will remain as a logical 1 until the end of the test sequence.

At the end of the test sequence performed by BIST 16, ATE 12 tests the cumulative difference output by memory device 10 as the test result for memory device under test 10. Any one bit of the cumulative difference that is a logical 1 indicates to the ATE that the memory device under test is faulty. However, the cumulative difference does not identify the one or more faulty memory locations.

While the above-described way of determining whether a difference exists between the any of the output patterns and the corresponding expected patterns and indicating such difference to the ATE at the end of the test sequence allows the ATE to operate deterministically, it also results in a loss of diagnostic information. Specifically, outputting the cumulative difference generated by difference detector and accumulator 22 at the end of the test sequence precludes identifying the test cycle in which the memory device under test generated a fault-indicating output pattern. Moreover, using the cumulative difference to represent all the differences detected during the test sequence precludes identifying the memory location(s) responsible for the fault-indicating output pattern(s) that caused the cumulative difference to indicate a faulty device. As noted above, such diagnostic information is highly important during production ramp and is important during on-going production.

Conventional BISTs such as those described above do not allow the ATE to react to a fault-indicating output pattern. The ATE has no indication that the memory device under test has generated a fault-indicating output pattern until the end of the test sequence. Moreover, information regarding the fault-indicating output pattern is lost as testing of the BIST continues after a fault-indicating output pattern has been received by difference detector and accumulator 22.

Accordingly, what is needed is a way to obtain diagnostic information from a memory circuit under test having a built-in self-test system.

### BRIEF DESCRIPTION OF THE DRAWINGS

FIG. 1A is a block diagram showing an example of a conventional memory device under test having a built-in test system (BIST) being tested by conventional automatic test equipment.

FIG. 1B is a flow chart illustrating the operation of the BIST shown in FIG. 1A to test the memory circuit that forms part of the memory device under test.

FIG. 1C is a block diagram showing an example of the difference detector and accumulator of the memory device shown in FIG. 1A.

FIG. 2 is a flow chart showing an example of a method in accordance with an embodiment of the invention for obtaining diagnostic information from a memory device having a BIST.

FIG. 3 is a block diagram showing an example of a system in accordance with an embodiment of the invention for obtaining diagnostic information from a memory device having a BIST and an example of a memory device having a BIST in accordance with an embodiment of the invention in which the memory device provides diagnostic information.

FIG. 4A is a block diagram showing an example of a diagnostic information collector that may be used as the diagnostic information collector in the memory device shown in FIG. 3.

FIG. 4B is a block diagram showing another example of a diagnostic information collector that may be used as the diagnostic information collector in the memory device shown in FIG. 3.

FIG. 5 is a block diagram showing an example of a comparator that may be used as the comparator in the diagnostic information collectors shown in FIGS. 4A and 4B.

FIG. 6A is a block diagram showing an example of a diagnostic information collector based on a conventional difference detector and accumulator.

FIG. 6B is a block diagram showing an exemplary channel of an embodiment of the diagnostic information collector shown in FIG. 6A in which the buffer comprises additional flip-flops.

FIG. 6C is a block diagram showing an exemplary channel of an embodiment of the diagnostic information collector shown in FIG. 6A in which the buffer stores output patterns as respective diagnostic patterns.

FIG. 7 is a block diagram showing another example of a diagnostic information collector that may be used as the diagnostic information collector in the memory device shown in FIG. 3.

FIGS. 8A and 8B are block diagrams showing examples of diagnostic information collectors that may be used as the diagnostic information collector in the memory device shown in FIG. 3 and examples of ATE that may be used as the ATE in the system shown in FIG. 3.

FIG. 9 is a flow chart showing an example of a method in accordance with an embodiment of the invention for obtaining diagnostic information from a memory device having a BIST in which the BIST suspends its normal testing operations from the time that it receives a fault indication until the diagnostic patterns have been output to the ATE.

FIG. 10 is a flow chart showing an example of a method in accordance with an embodiment of the invention for obtaining diagnostic information from a memory device having a BIST in which the BIST continues to perform normal testing operations until the ATE indicates that it is ready to receive stored diagnostic patterns.

### DETAILED DESCRIPTION

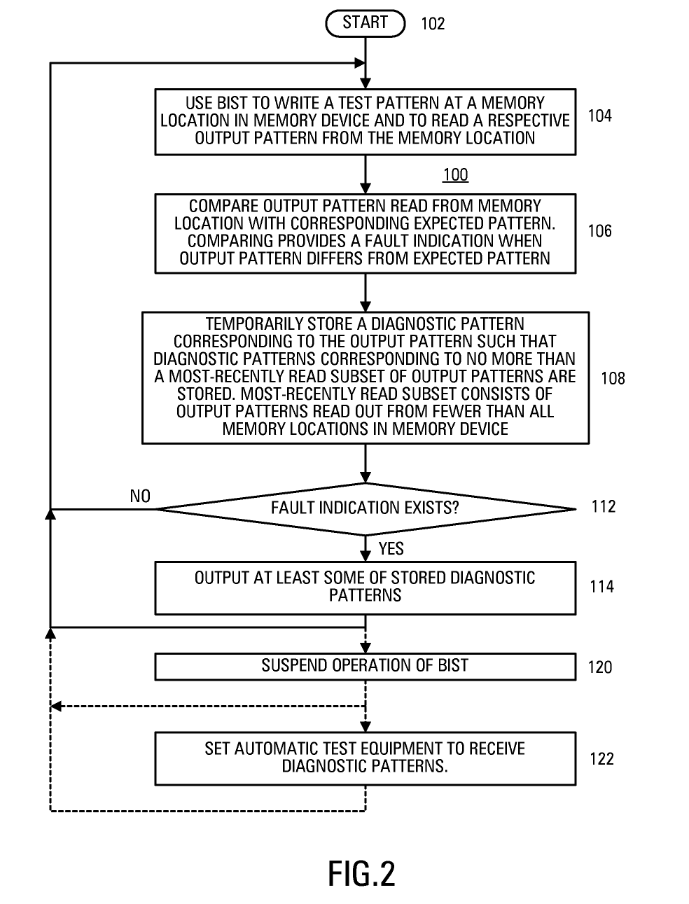

FIG. 2 is a flow chart showing an example of a method 100 in accordance with an embodiment of the invention for obtaining diagnostic information from a memory device having a built-in self-test system (BIST). Execution starts at block 102. In block 104, the BIST is used to write a test pattern at a memory location in the memory device and to read a respective output pattern from the memory location.

In block 106, the output pattern read from the memory circuit is compared with a corresponding expected pattern. The comparing provides a fault indication FI when the output pattern differs from the corresponding expected pattern. The corresponding expected pattern is a pattern identical to the test pattern written at the memory location from which the output pattern was read. In an example, the corresponding expected pattern is a subsequently-generated pattern identical to the test pattern that was written.

Concurrently, in block 108, a diagnostic pattern corresponding to the output pattern is temporarily stored such that diagnostic patterns corresponding to no more than a most-recently read subset of the output patterns are stored. The most-recently read subset of the output patterns is composed of the output patterns read from fewer than all memory locations in the memory device.

In one embodiment, the output pattern read from the memory location is stored as the diagnostic pattern. In another embodiment, a difference pattern representing a difference between the output pattern read from the memory location and the corresponding expected pattern is stored as the diagnostic pattern. A diagnostic pattern consisting of an output pattern or a diagnostic pattern consisting of a difference pattern that represents the difference between an output pattern and a corresponding expected pattern will be regarded as a diagnostic pattern corresponding to the output pattern. In both embodiments, the output pattern is the output pattern read from the memory location in block 104.

In block 112, a test is performed to determine whether the fault indication exists. A YES result in block 112 causes execution to advance to block 114, where at least some of the stored diagnostic patterns are output. A NO result in block 112 causes execution to return to block 104, where normal BIST operation continues.

In an embodiment of method 100, in block 104, the BIST generates a single test pattern, writes such test pattern at a single memory location in the memory device and reads a respective output pattern from such single memory location. The BIST additionally generates the test pattern anew as the corresponding expected pattern for comparison with the output pattern in block 106. Alternatively, the BIST may store the original test pattern and output the stored test pattern as the corresponding expected pattern for comparison with the output pattern in block 106.

In another embodiment, the BIST generates a single test pattern, writes such test pattern at multiple memory locations in the memory device and sequentially reads respective output patterns from the memory locations at which the test pattern was written. The BIST repetitively generates the test pattern anew as the corresponding expected pattern for comparison with the output patterns in block 106. Alternatively, the BIST may store the original test pattern and repetitively output the stored test pattern as corresponding expected patterns for comparison with the output patterns in block 106.

In yet another embodiment, the BIST generates multiple test patterns, writes such test patterns at multiple memory locations in the memory device and sequentially reads respective output patterns from the memory locations at which the test patterns were written. The BIST additionally generates the multiple test patterns anew as corresponding expected patterns for comparison with the output patterns in block 106. Alternatively, the BIST may store the original test patterns and output the stored test patterns as corresponding expected patterns for comparison with the output patterns in block 106.

Other writing and reading schemes are possible as long as the output pattern read from each memory location is compared with its corresponding expected pattern and a diagnostic pattern corresponding to the output pattern read from the memory location is temporarily stored. The diagnostic pattern is stored such that diagnostic patterns corresponding to no more than a most-recently read subset of the output patterns are stored, as described above.

A memory device under test that performs an embodiment of method 100 is typically tested by connecting it to automatic test equipment (ATE). The ATE initializes the BIST controller in the memory device under test, determines whether the memory device under test has passed or failed the testing and receives the stored diagnostic patterns output in block 114.

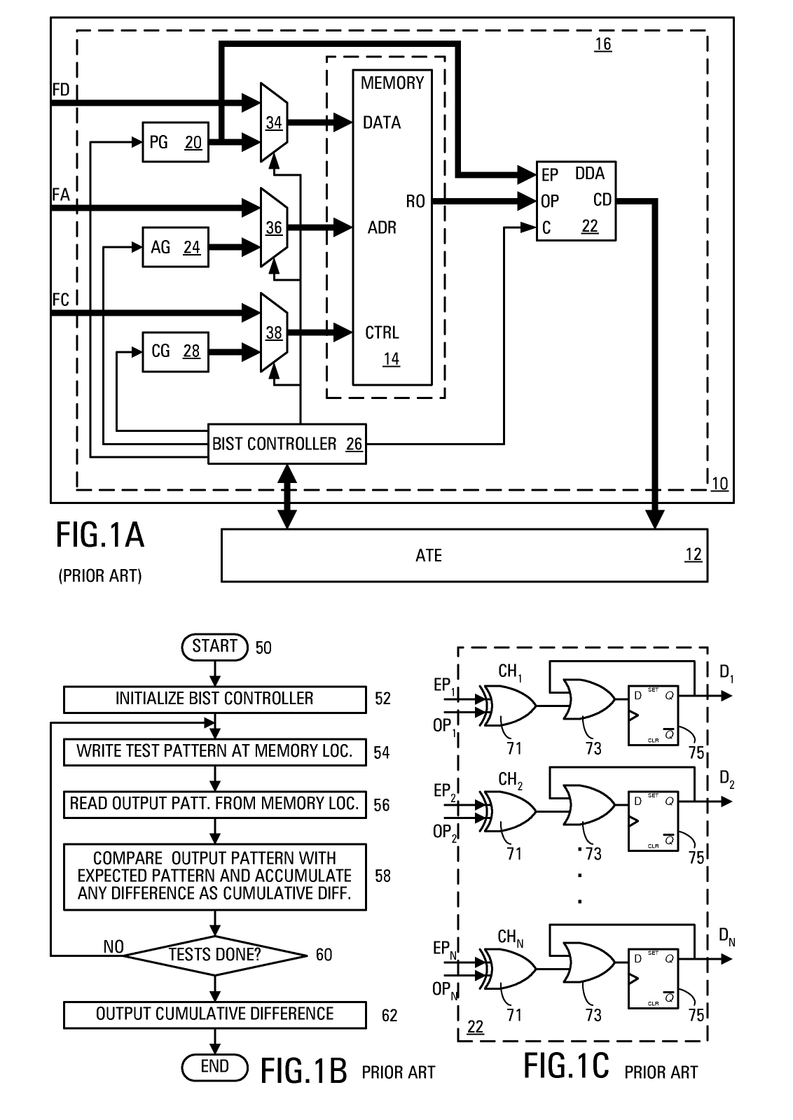

Unlike the conventional test process described above with reference to FIG. 1B, when an output pattern differs from its corresponding expected pattern, embodiments of method 100 in accordance with the invention test output the stored diagnostic information to the ATE in response to the resulting fault indication. Since a fault indication can occur at any point in the test sequence performed by the BIST, ATE suitable for testing a memory device that performs an embodiment of method 100 differs from conventional ATE in that such ATE is capable of behaving non-deterministically. Such capability enables the ATE, at any point during the test sequence performed by the BIST, to suspend its normal testing operations and receive the stored diagnostic patterns output in block 114. In automatic test equipment that tests more than one memory device under test at a time, normal testing operations are suspended only with respect to the memory device under test that provides the fault indication in block 108: the ATE continues testing the remaining memory devices under test uninterrupted. Regardless of the number of memory devices under test that are tested at a time, the ATE typically requires a finite output time to respond to the fault indication by suspending its normal testing operations, preparing to receive and then receiving the diagnostic patterns.

As noted above, in block 108, the diagnostic pattern is temporarily stored such that diagnostic patterns corresponding to a most-recently read subset of the output patterns are stored. The number of output patterns in the most-recently read subset of the output patterns is small compared with the total number of output patterns read during testing of the memory device under test. Consequently, the number of diagnostic patterns stored in block 106 is relatively small, so that storage for the diagnostic patterns can be provided in the memory device under test without significantly increasing the cost and complexity of the memory device.

An output pattern read in block 104 that differs from its corresponding expected pattern is a fault-indicating output pattern and causes a fault indication to be provided in block 106. As noted above, a finite output time is needed before a fault-indicating diagnostic pattern corresponding to the fault-indicating output pattern can be output in block 114. Consequently, the fault-indicating diagnostic pattern is stored in block 108 until it can be output in block 114. The most-recently read subset of the output patterns is composed of the output patterns read during the output time. As will be described in more detail below, storage is provided in the memory device sufficient to accommodate all the diagnostic patterns corresponding to the most-recently read subset of the output patterns without overwriting or otherwise destroying the stored fault-indicating diagnostic pattern.

The flow chart shown in FIG. 2 additionally shows some operations that optionally can constitute part of embodiments of method 100. Such operations are performed in addition to the output of stored diagnostic patterns performed in block 114 when a YES result is obtained in block 112, i.e., when the comparison performed in block 106 indicates a fault. The additional operations need not be performed in the order shown.

In the example of method 100 shown in FIG. 2, a YES result in block 112 automatically prevents the BIST from performing further write and read operations in block 104 until the stored diagnostic patterns have been output in block 114. Preventing the BIST from performing further read and write operations after existence of the fault-indication has been determined minimizes the number of diagnostic patterns that need to be stored, and, hence, the size of the storage needed for the diagnostic patterns. In other embodiments of method 100, a YES result in block 112 does not automatically prevent the BIST from performing additional write and read operations. Allowing the BIST to operate normally during the output time requires considerable more storage. The amount of storage needed depends on the output time and the rate at which output patterns are read. Method 100 can include block 120 to reduce the size of the storage. In block 120, the normal testing operations of the BIST are temporarily suspended when a YES result is obtained in block 112. This prevents more output patterns from being read from memory device 14 and eliminates the need to store corresponding diagnostic patterns in block 108 while the diagnostic patterns are output in block 114. In one embodiment, operation of the BIST is typically suspended only while the stored diagnostic patterns are output in block 114. In another embodiment, operation of the BIST is suspended immediately when a fault indication is determined to exist in block 112 and is not resumed until the stored diagnostic patterns have all been output in block 114. This embodiment also minimizes the size of the storage.

A memory device under test that performs an embodiment of method 100 is typically connected to automatic test equipment (ATE). The ATE initializes a BIST controller at least at the start of testing, determines whether the memory device under test has passed or failed the testing and receives the stored diagnostic patterns output in block 114. ATE that tests more than one memory device under test at a time typically suspends its normal testing operations only with respect to the memory device under test from which the diagnostic patterns are output in block 114: testing operations performed on the remaining memory devices under test continue uninterrupted.

Embodiments of method 100 that output the stored diagnostic patterns to a non-deterministic ATE as described above additionally comprise block 122 in which the ATE is set to receive the stored diagnostic patterns output in block 114. In an embodiment, the fault indication generated in block 106 is provided to the ATE in block 122. The fault indication indicates to the ATE that a fault has been detected and that stored diagnostic patterns are available for output.

The ATE periodically checks whether the fault indication exists and executes a diagnostic information receiving routine when it determines that the fault indication exists. In another embodiment, the fault indication provided to the ATE in block 122 operates as an interrupt that immediately causes the ATE to suspend its normal testing operations and execute a diagnostic information receiving routine in which it receives the diagnostic patterns output in block 114. Additional handshaking operations between the memory device and the ATE may be performed in connection with the execution of block 122. Such handshaking operations typically involve the ATE indicating that it is ready to receive the stored diagnostic patterns, and an indication to the ATE that all the stored diagnostic patterns have been downloaded. Such handshaking may take a non-trivial time.

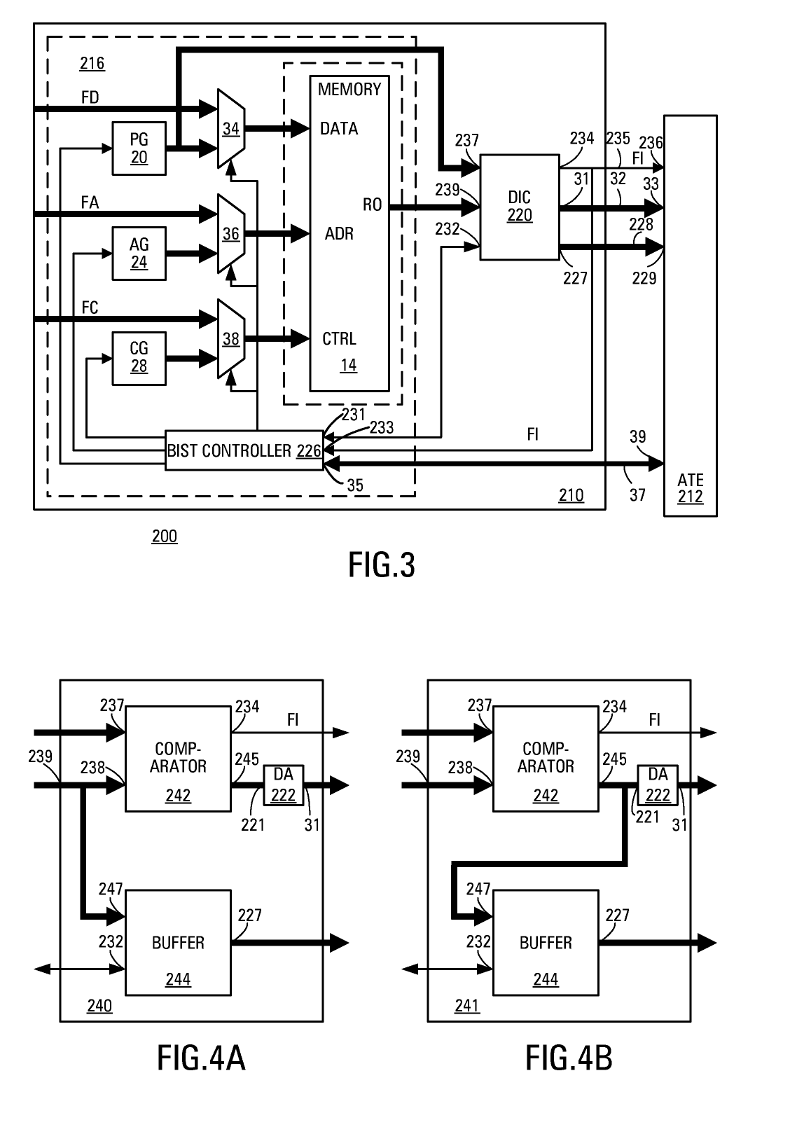

Method 100 is performed by a diagnostic information collector built into the memory device under test. Examples of such diagnostic information collector will be described below with reference to FIGS. 3-8B. In some embodiments, few, if any, additional communication channels are needed between the memory device under test and host automatic test equipment (ATE) to which the diagnostic information collector outputs the temporarily-stored diagnostic patterns in the event that the comparison performed in block 106 indicates provides a fault indication.

FIG. 3 is a block diagram showing an example of a system 200 in accordance with an embodiment of the invention for obtaining diagnostic information from a memory device having a built-in self-test system (BIST). FIG. 3 additionally shows an example of a memory device under test 210 in accordance with an embodiment of the invention. System 200 and memory device 210 each perform a respective embodiment of method 100 described above with reference to FIG. 2 to provide diagnostic information. System 200 comprises memory device 210 and ATE 212. Memory device 210 comprises a memory circuit 14, a built-in self-test system (BIST) 216 and a diagnostic information collector (DIC) 220.

The example of BIST 216 shown in FIG. 3 is composed of a pattern generator (PG) 20, an address generator (AG) 24, a control signal generator (CG) 28 and multiplexers 34, 36, and 38. Each multiplexer 34, 36 and 38 has two inputs and an output. Pattern generator 20, address generator 24 and control signal generator 28 are connected to one input of multiplexers 34, 36 and 38, respectively, and the functional data input FD, the functional address input FA and the functional control input FC of memory device 210 are connected to the other input of multiplexers 34, 36 and 38, respectively. Functional data input FD, functional address input FA and functional control input FC of memory device 210 are the inputs used for data, address and control signals, respectively, during in-service operation of memory device 210, i.e., during operation of memory device 210 except when it is being tested using BIST 216. The data input (DATA), address input (ADR) and control input (CTRL) of memory circuit 14 are connected to the outputs of multiplexers 34, 36 and 38, respectively.

During in-service operation of memory device 210, multiplexers 34, 36 and 38 connect the functional data input FD, the functional address input FA and the functional control input FC, respectively, of memory device 210 to the data input (DATA), address input (ADR) and control input (CTRL), respectively, of memory circuit 14.

BIST 216 additionally comprises a BIST controller 226 that communicates with ATE 212 via control port 35, control port 39 and control path 37. BIST controller 226 generates control signals that control the operation of pattern generator 20, address generator 24, control signal generator 28, multiplexers 34, 36 and 38, and diagnostic information collector 220. During testing of memory device 210, the control signals output by BIST controller 226 cause multiplexers 34, 36 and 38 to connect the outputs of pattern generator 20, address generator 24, control signal generator 28, respectively, to the data input (DATA), address input (ADR) and control input (CTRL), respectively, of memory circuit 14. Control signals output by BIST controller 226 additionally cause pattern generator 20, address generator 24, control signal generator 28 to generate the test patterns and expected patterns, the addresses and the WRITE and READ commands, respectively, used to test memory circuit 14. Additionally, BIST controller 226 exchanges control signals with the control port 39 of ATE 212 via control port 35 and control path 37.

Diagnostic information collector 220 has an expected pattern input 237 and an output pattern input 239. Output pattern input 239 is connected to the read output (RO) of memory circuit 14 to receive the output patterns read from the memory locations of memory circuit 14 defined by the addresses generated by address generator 24 and in response to the control signals generated by control signal generator 28. Expected pattern input 237 is connected to the output of pattern generator 20 to receive a corresponding expected pattern corresponding to each output pattern received at output pattern input 239. As indicated above, each expected pattern is identical to the test pattern written at the memory location of memory circuit 14 from which the output pattern was read.

Diagnostic information collector 220 additionally has a fault indication output 234, a control port 232, a diagnostic pattern output 227 and a test result output 31. Fault indication output 234 is internally coupled to a fault indication input 233 of BIST controller 226. Control port 232 is internally coupled to a control port 231 of BIST controller 226.

Diagnostic information collector 220 includes the above-mentioned test result output 31 and generates a test result that is output at test result output 31 to provide compatibility with conventional memory test routines executed by ATE 212. Test result output 31 and its associated difference accumulator 222 (described below with reference to FIG. 4A) may be omitted from diagnostic information collector 220 in versions of memory device 210 intended for testing by an embodiment of ATE 212 that executes a modified memory test routine capable of determining a test result for memory device under test 210 instead of receiving a test result from the memory device under test. For example, such modified memory test routine can determine the test result for the memory device under test by determining whether the ATE received fault indication FI or diagnostic information while it was testing the memory device under test.

Diagnostic information collector 220 stores diagnostic patterns corresponding to the output patterns read from memory circuit 14. In one embodiment, the diagnostic information collector stores the output patterns received from memory circuit 14 at output pattern input 239 as corresponding diagnostic patterns. In another embodiment, the diagnostic information collector stores difference patterns representing respective differences between the output patterns received from memory circuit 14 at output pattern input 239 and the corresponding expected patterns received at expected pattern input 237 as corresponding diagnostic patterns.

Diagnostic information collector 220 additionally compares each output pattern with its corresponding expected pattern to detect any difference between the output pattern and its corresponding expected pattern. A difference between the output pattern and its corresponding expected pattern causes diagnostic information collector 220 to provide a fault indication at fault indication output 234. Otherwise, diagnostic information collector 220 provides no fault indication at fault indication output 234.

ATE 212 initiates testing memory device under test 210 by providing a start testing command to BIST controller 226 via control path 37. During operation of BIST 216 to test memory device under test 210, control signal generator 28 generates a control signal that sets memory circuit 14 to its write mode, address generator 24 generates an address signal that defines a memory location in memory circuit 14 and pattern generator 20 generates a test pattern that is written at the memory location in memory circuit 14. In response to further control signals provided by BIST controller 226, address generator 24 generates an address signal that again defines the memory location in memory circuit 14 at which the test pattern was written, control signal generator 28 generates a control signal that sets memory circuit 14 to its read mode, and memory circuit 14 reads a respective output pattern from the memory location defined by the address signal. The output pattern is input to diagnostic information collector 220 at output pattern input 239. Additionally, pattern generator 20 generates an expected pattern identical to the test pattern that was written at the memory location and outputs the expected pattern as the expected pattern corresponding to the output pattern to the expected pattern input 237 of diagnostic information collector 220.

Diagnostic information collector 220 temporarily stores a diagnostic pattern corresponding to the output pattern such that the diagnostic patterns corresponding to no more than a most-recently read subset of output patterns are stored. The most-recently read subset of output patterns is composed of output patterns read from fewer than all the memory locations in memory device 210, i.e., in memory circuit 14. In one embodiment, the output pattern received at output pattern input 239 is stored as the diagnostic pattern corresponding to the output pattern. In another embodiment, the difference pattern representing the difference between the output pattern received at output pattern input 239 and the corresponding expected pattern received at expected pattern input 237 is stored as the corresponding diagnostic pattern corresponding to the output pattern. No difference, as occurs when the output pattern and its corresponding expected pattern are identical, is regarded herein as being a special case of a difference.

In the event that storage for the diagnostic patterns within diagnostic information collector 220 becomes full, the diagnostic information collector provides a control signal at control port 232. Received at the control port 231 of BIST controller 226, the control signal instructs BIST controller 226 to command BIST 216 to suspend its normal testing operations until the stored diagnostic patterns can be output.

Diagnostic information collector 220 additionally compares the output pattern read from the memory location and received at output pattern input 239 with the corresponding expected pattern received at expected pattern input 237, and provides fault indication FI at fault indication output 234 when the output pattern differs from the corresponding expected pattern.

Finally, diagnostic information collector 220 generates a cumulative difference that, at the end of the test sequence performed by BIST 226, it outputs at a test result output 31 as the test result for memory device under test 210.

ATE 212 has a test result input 33, a control port 39, diagnostic information input 229 and a fault indication input 236. A test result path 32 connects test result input 33 to the test result output 31 of diagnostic information collector 220. The test result path and the test result input may be omitted in an embodiment of ATE 212 capable of determining a test result for memory device under test 210 instead receiving a test result from the memory device under test.

A control path 37 connects control port 39 to a control port 35 of BIST controller 226. BIST controller 226 controls the operation of BIST 216 in response to control signals provided by ATE 212 via control path 37 and additionally provides status information to ATE 212 via control path 37. A diagnostic pattern path 228 connects diagnostic pattern input 229 to the diagnostic pattern output 227 of diagnostic information collector 220. A fault indication path 235 connects fault indication input 236 to the fault indication output 234 of diagnostic information collector 220.

In response to fault indication FI, diagnostic information collector 220 outputs at least some of the stored diagnostic patterns to ATE 212. Diagnostic information collector 220 outputs the diagnostic patterns at diagnostic pattern output 227 connected by diagnostic pattern output path 228 to the diagnostic pattern input 229 of ATE 212. In an embodiment, fault indication FI provided at fault indication output 234 of diagnostic information collector 220 is received by ATE 212 and BIST controller 226. Fault indication FI provided at fault indication output 234 indicates to ATE 212 that a fault has been detected. In response to this indication ATE 212 sets itself to a state in which it can receive the output diagnostic patterns, and provides a ready signal to BIST controller 226 via control path 37. In response to fault indication FI and the ready signal, BIST controller 226 provides a control signal at control port 231. Such control signal is received at the control port 232 of diagnostic information collector 220 and causes diagnostic information collector 220 to output the stored diagnostic patterns.

The diagnostic patterns output to ATE 212 provide diagnostic information relating to memory device 210. Specifically, the diagnostic patterns indicate the nature of the failure, e.g., the erroneous output pattern, but as described above, do not identify the location of the failure, i.e., the address of the faulty memory location. Location information can be provided in two ways. First, during testing of memory device 210, BIST controller 226 keeps track of the memory location under test. Consequently, as part of the process of receiving the diagnostic patterns, the ATE can provide control signals via control path 37 to cause BIST controller 226 to output via control path 37 the address of the current memory location as the location information. This way of providing location information requires that no storage be provided in diagnostic information collector 220 for the location information, but requires that BIST 216 suspend its normal testing operations immediately in response to fault indication FI.

In a second way of providing location information, diagnostic information collector 220 has an additional input (not shown) connected to the output of address generator 24 to receive the address of the memory location from which the output pattern received at output pattern input 239 was read. In such an embodiment, each diagnostic pattern is composed of the diagnostic pattern as described above, i.e., the output pattern or the difference pattern, concatenated with the respective address received from address generator 24. The address that forms part of each diagnostic pattern provides the location information that allows the defective memory location to be identified. This way of providing location information requires that diagnostic information collector 220 provide storage for the location information that additionally constitutes part of the stored diagnostic patterns, but does not require that BIST 216 suspend its normal testing operations in response to fault indication FI.

FIG. 4A is a block diagram showing an example of a diagnostic information collector 240 that may be used as diagnostic information collector 220 in memory device 210 described above with reference to FIG. 3. Diagnostic information collector 240 will be described with additional reference to FIG. 3. Diagnostic information collector 240 comprises a comparator 242, a buffer 244 and a difference accumulator (DA) 222. In diagnostic information collector 240, buffer 244 stores each output pattern received at output pattern input 239 as the diagnostic pattern corresponding to the output pattern.

Comparator 242 has an expected pattern input, an output pattern input 238, a difference pattern output 245 and a fault indication output. The expected pattern input and fault indication output of comparator 242 provide the expected pattern input 237 and fault indication output 234, respectively, of diagnostic information collector 240. Output pattern input 238 is connected to the output pattern input 239 of diagnostic information collector 240.

Referring additionally to FIG. 3, in operation of comparator 242, expected pattern input 237 receives the corresponding expected pattern output by pattern generator 20 during each read operation performed by memory circuit 14. Output pattern input 238 receives from the output pattern input 239 of diagnostic information collector 220 the output pattern output by memory circuit 14 during each read operation. Comparator 242 compares each output pattern with its corresponding expected pattern to generate a fault indication signal that it outputs at fault indication output 234, and additionally to generate a difference pattern that it outputs at difference output 245.

The difference pattern generated by comparator 242 provides a bit-by-bit indication of the modulus of any difference between the output pattern and the corresponding expected pattern. Typically, the output pattern is identical to the corresponding expected pattern. In this case, the comparison performed by comparator 242 provides the fault indication signal in a state that provides no fault indication, and the difference pattern output by comparator 242 has a logical zero in every bit position. When the output pattern differs from the corresponding expected pattern, the comparison performed by comparator 242 generates the fault indication signal in a state that provides fault indication FI. Additionally, the difference pattern output by comparator 242 has a logical one at each bit position at which the output pattern differs from the corresponding expected pattern and has a logical zero at each remaining bit position. The logical ones and logical zeroes may be interchanged.

Difference accumulator 222 has a difference pattern input 221 and a test result output. Difference pattern input 221 is connected to the difference pattern output 245 of comparator 242. The test result output of difference accumulator 222 provides the test result output 31 of diagnostic information collector 240. In operation, difference accumulator accumulates the difference patterns output by comparator 242 so that at the end of the test sequence performed by BIST 216, the test result output 31 of the difference accumulator has a logical one at every bit position at which one of the output patterns has differed from its corresponding expected pattern.

As noted above, difference accumulator 222, test result output 31 and the difference pattern output 245 of comparator 242 may be omitted from diagnostic information collector 240 in versions of memory device 210 intended for testing by an embodiment of ATE 212 capable of determining a test result for the memory device under test instead of receiving a test result from the memory device under test.

Buffer 244 has a control port, a diagnostic pattern input 247 and a diagnostic pattern output. The control port and diagnostic pattern output of buffer 244 provide the control port 232 and diagnostic pattern output 227 of diagnostic information collector 240. In the example shown in FIG. 4A, diagnostic pattern input 247 is connected to the output pattern input 239 of diagnostic information collector 240 and receives each output pattern received at output pattern input 239 as the diagnostic pattern corresponding to the output pattern.

An embodiment of buffer 244 that additionally stores a respective address as part of each diagnostic pattern additionally has an address input (not shown) connected to the output of address generator 24. The width of such an embodiment of buffer 244 is greater than that of an embodiment in which the diagnostic patterns lack respective addresses. The increase in width is equal to the width of the addresses.

In operation, the example of buffer 244 shown in FIG. 4A receives via diagnostic pattern input 247 the output pattern read from memory circuit 14 in each read operation as a respective diagnostic pattern. Buffer 244 additionally receives via control port 232 one or more control signals from BIST controller 226. In response to the control signals, buffer 244 temporarily stores each diagnostic pattern received at diagnostic pattern input 247.

In an embodiment, either or both of comparator 242 and buffer 244 comprises additional logic (not shown) controlled by BIST controller 226. Such additional logic ensures that comparator 242 can generate a fault indication and a difference pattern and that buffer 244 can store a difference pattern only when BIST controller 226 is in a compare state.

Buffer 244 stores each newly-received diagnostic pattern in such a way that the newly-received diagnostic pattern replaces the oldest diagnostic pattern stored in the buffer. Typical replacement methods include overwriting the oldest diagnostic pattern stored in the buffer with the newly-received diagnostic pattern and shifting the oldest diagnostic pattern out of the buffer as the newly-received diagnostic pattern is shifted into the buffer. By replacing the oldest diagnostic pattern with the newly-received diagnostic pattern, buffer 244 always temporarily stores the diagnostic patterns corresponding to the N most-recently performed read operations, where N is less than the total number of read operations needed to read all of the memory locations in memory circuit 14. By storing only the diagnostic patterns corresponding to the output patterns read in what is typically a small subset of the total number of read operations performed to read all the memory locations in memory circuit 14, the size of buffer 244 can be relatively small. Minimizing the size of buffer 244 is highly desirable to minimize the cost of incorporating diagnostic information collector 220 in memory device 210. However, the number of diagnostic patterns stored in buffer 244 must be sufficient to ensure that, when comparator 242 provides fault indication FI, the fault-indicating diagnostic pattern corresponding to the fault-indicating output pattern that caused comparator 242 to provide fault indication FI has not been replaced by a diagnostic pattern subsequently stored in buffer 244, as discussed above. The number of diagnostic patterns stored depends in part on whether and how BIST 216 suspends its normal testing operations in response to fault indication FI.

In other embodiments, the diagnostic patterns are successively presented to the diagnostic pattern input 247 of buffer 244 but buffer 244 does not store them. Only when fault indication FI is additionally provided to buffer 244 does the buffer store the diagnostic patterns received at diagnostic pattern input 247.

FIG. 4B is a block diagram showing another example of a diagnostic information collector 241 that may be used as diagnostic information collector 220 in memory device 210 described above with reference to FIG. 3. Diagnostic information collector 241 will be described with additional reference to FIG. 3. Diagnostic information collector 241 comprises comparator 242, buffer 244 and difference accumulator 222. In this embodiment, the difference pattern generated by comparator 242 from each output pattern received at output pattern input 239 and its corresponding expected pattern received at expected pattern input 237 is stored by buffer 244 as the diagnostic pattern corresponding to the output pattern received at output pattern input 239.

The structure and operation of comparator 242, buffer 244 and difference accumulator 222 are identical to those of the corresponding elements of diagnostic information collector 240 described above with reference to FIG. 4A. However, in diagnostic information collector 241, the diagnostic pattern input 247 of buffer 244 is connected to the difference pattern output 245 of comparator 242. Consequently, in diagnostic information collector 241, buffer 244 stores as a respective diagnostic pattern the difference pattern generated by comparator 242 from the output pattern read from the memory location of memory circuit 14 in each read operation and its corresponding expected pattern.

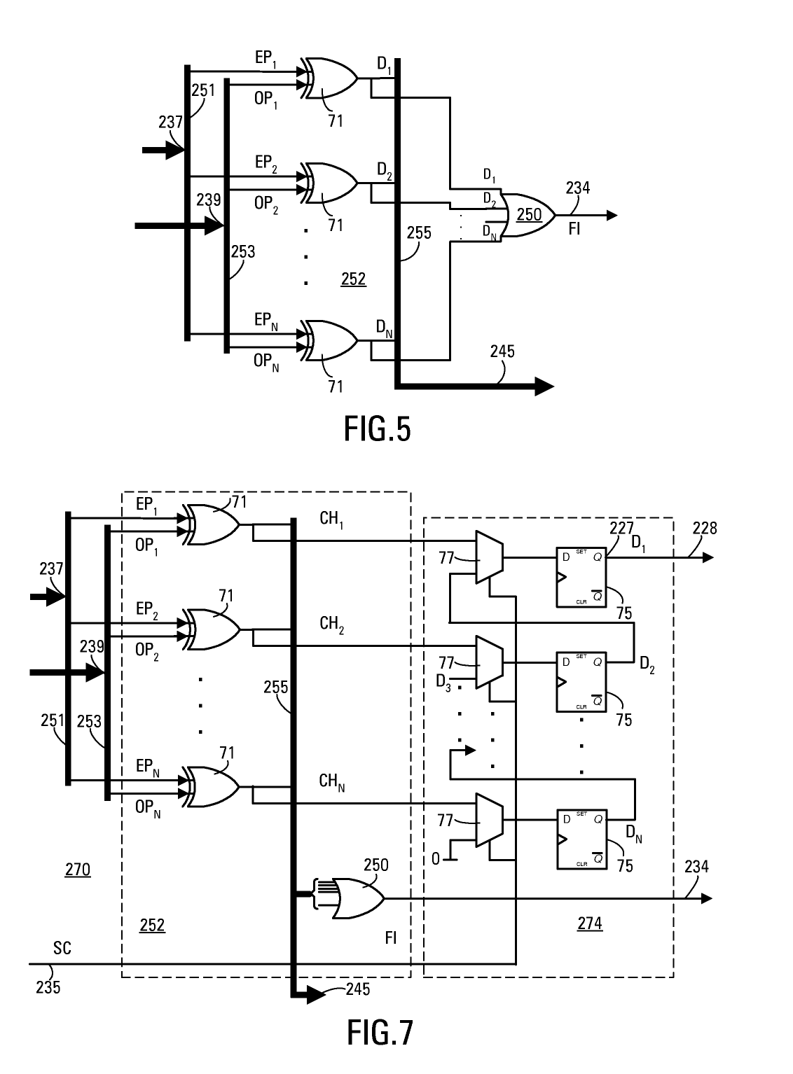

FIG. 5 is a block diagram showing an example of a comparator 252 that may be used as comparator 242 in diagnostic information collectors 240 and 241 described above with reference to FIGS. 4A and 4B, respectively. Comparator 252 will be described with additional reference to FIG. 4A. Elements of comparator 252 that correspond to elements of above-described comparator 242 are indicated by the same reference numerals and will not be described in detail again.

In the example shown, the output pattern read from memory circuit 14 and the corresponding expected pattern generated by pattern generator 20 are each N-bit quantities.

Comparator 252 is composed of N two-input exclusive-OR (XOR) gates 71 and an N-input OR gate 250. A respective conductor (not shown) of an expected pattern bus 251 connects one input of each XOR-gate 71 to expected pattern input 237. A respective conductor (not shown) of an output pattern bus 253 connects the other input of each XOR-gate 71 to output pattern input 239. A respective conductor (not shown) of a difference pattern bus 255 connects the output of each XOR gate 71 to difference pattern output 245. The output of each XOR gate 71 is additionally connected to a respective input of OR gate 250. The output of OR gate 250 provides the fault indication output 234 of diagnostic information collector 220.

The output of each XOR gates 71 provides a respective bit D₁, D₂, . . . , D_{N} of a difference pattern D that represents the modulus of the difference between each bit of the output pattern received at output pattern input 239 and the corresponding bit of the corresponding expected pattern received at expected pattern input 237. Difference pattern bus 255 connects each difference pattern collectively generated by XOR gates 71 to difference pattern output 245.

Each XOR gate 71 receives at its inputs a respective bit (e.g., bit OP₁) of the output pattern and the corresponding bit (e.g., bit EP₁) of the corresponding expected pattern. Typically, each bit of the output pattern is identical to the corresponding bit of the corresponding expected pattern so that the output of each XOR gate 71 is in a logical 0 state. OR gate 250 receives the outputs of the XOR gates each in a logical 0 state and, in response, outputs the fault indication signal in a logical 0 state that provides no fault indication.

A difference between any bit of the output pattern and the corresponding bit of the corresponding expected pattern sets the output of the respective XOR gate to a logical 1 state. The output of any one or more of the XOR gates 71 in a logical 1 state causes OR gate 250 to output the fault indication signal in a logical 1 state that provides fault indication FI.

Referring again to FIGS. 3, 4A and 4B, in some embodiments of diagnostic information collector 220, buffer 244 is embodied as a respective first in, first out shift register (not shown) connected to diagnostic pattern input 247. The number of stages in each shift register depends on the maximum number of read cycles that BIST 216 can perform on memory circuit 14 between comparator 242 providing fault indication FI at fault indication output 234 and completion of the output process for the stored diagnostic patterns. The width of the shift register depends on the number of bits in each diagnostic pattern.

In other embodiments, buffer 244 is embodied as random access memory (not shown) and a memory controller (not shown) that controls the operation of the random access memory. In one embodiment, during each read operation performed by BIST 216 on memory circuit 14, the memory controller performs simultaneous buffer-write operations on memory cells (not shown) in buffer 244 equal in number to the number of bits in each diagnostic pattern. Additionally, the memory controller increments the buffer write address in a round-robin pattern so that, in each buffer-write operation, the newly-written diagnostic pattern overwrites the oldest diagnostic pattern stored in the buffer. The number of memory cells constituting buffer 244 is at least that which allows a number of buffer-write operations equal to the maximum number of read operations that BIST 216 performs on memory circuit 14 between comparator 242 providing fault indication FI at fault indication output 234 and completion of the output process for the stored diagnostic patterns. This prevents a fault-indicating diagnostic pattern stored earlier in the testing from being overwritten by subsequently-stored diagnostic patterns. The size of buffer 244 may be reduced by causing BIST 216 to stop performing its normal testing operations when comparator 242 provides fault indication FI, or when the output process for the stored diagnostic patterns begins, as will be described below.

In response to a read instruction received from BIST controller 226 via control port 232, buffer 244 outputs its contents to diagnostic pattern output 227 for output to ATE 212 via diagnostic pattern output path 228. In some embodiments, buffer 244 incorporates a multiplexer (not shown) interposed between its memory elements (memory cells or shift registers) and diagnostic pattern output 227. Such multiplexer multiplexes the diagnostic patterns read from the memory elements in parallel to generate a serial bit stream. Outputting the diagnostic patterns serially allows diagnostic pattern output 227 and diagnostic pattern output path 228 each to be configured as single channel components.

In embodiments in which fault indication FI output at fault indication output 234 causes BIST 216 to stop performing its normal testing operations until the stored diagnostic patterns have been output, the depth of buffer 244 can be relatively small. In such embodiments, the structure of the conventional difference detector and accumulator (22 in FIG. 1C) can be modified to provide diagnostic information collector 220.

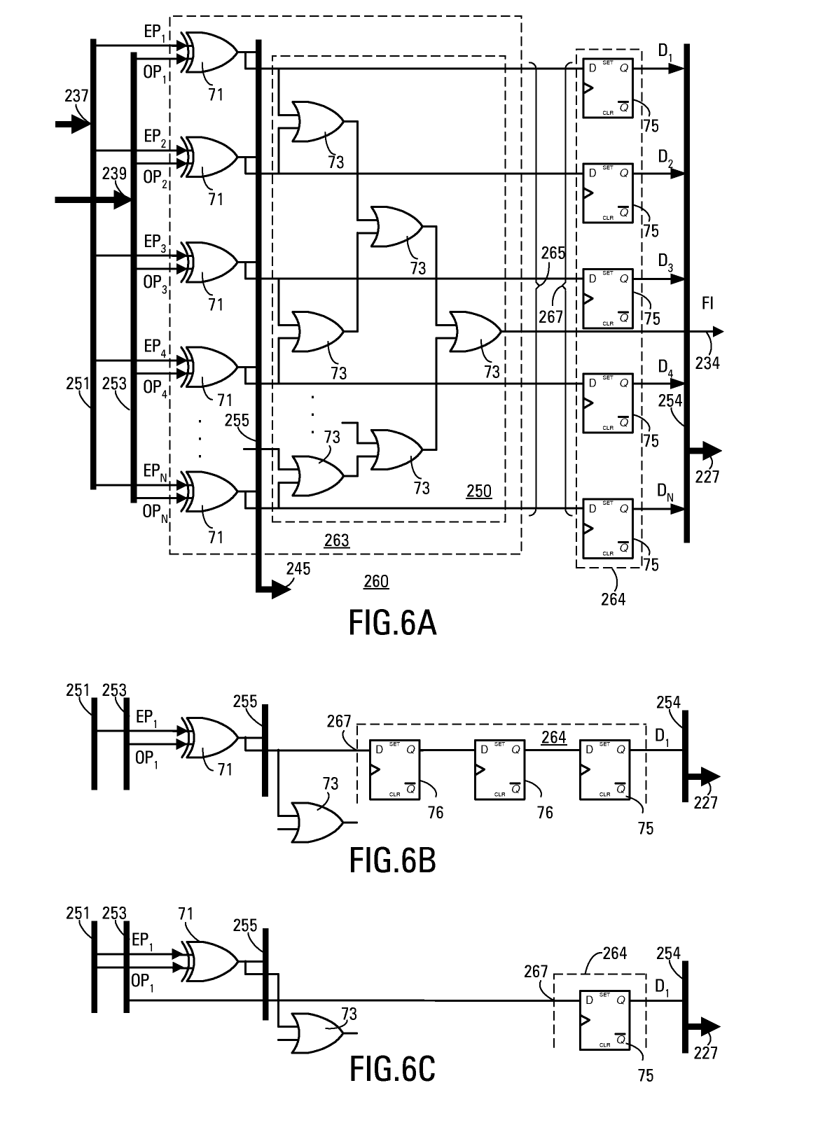

FIG. 6A is a block diagram showing an example of an embodiment of a diagnostic information collector 260 based on a conventional difference detector and accumulator such as that shown at 22 in FIG. 1C. Diagnostic information collector 260 can be used as diagnostic information collector 220 in system 200 and memory device 210 described above with reference to FIG. 3. Diagnostic information collector 260 is composed of a comparator 263 and a buffer 264.

Comparator 263 is similar in structure to comparator 253 described above with reference to FIG. 5. Comparator 263 is composed of the N two-input exclusive-OR (XOR) gates 71 that constitute part of conventional difference detector and accumulator 22 and an N-input OR gate 250. A respective conductor (not shown) of expected pattern bus 251 connects one input of each XOR-gate 71 to expected pattern input 237. A respective conductor (not shown) of output pattern bus 253 connects the other input of each XOR-gate 71 to output pattern input 239. A respective conductor (not shown) of difference pattern bus 255 connects the output of each XOR gate 71 to difference pattern output 245. The output of each XOR gate 71 is additionally connected to a respective input of OR gate 250. The output of OR gate 250 provides the fault indication output 234 of diagnostic information collector 220.

In this example, N-input OR gate 250 is constructed by connecting N-1 of the two-input OR gates 73 that constitute part of conventional difference detector and accumulator 22 (FIG. 1C) in cascade such that the inputs of N/2 OR gates 73 are connected to the outputs of XOR gates 71, the inputs of N/4 OR gates 73 are connected to the outputs of the N/2 OR gates 73 and so on until the inputs of a single OR gate 73 are connected to the outputs of two OR gates 73. The output of the single OR gate 73 provides the fault indication output 234 of diagnostic information collector 260. Alternatively, a single N-input OR gate can be used as OR gate 250, as described above with reference to FIG. 5.

The outputs of the XOR gates 71 additionally collectively provide an internal difference pattern output 265 of comparator 263 that is connected to a diagnostic pattern input 267 of buffer 264.

In diagnostic information collector 260, buffer 264 is composed of the N flip-flops 75 that additionally constitute part of conventional difference detector and accumulator 22 (FIG. 1C). The D-input of each flip-flop is connected via diagnostic pattern input 267 and difference pattern output 265 to the output of a respective XOR gate 71. A respective conductor (not shown) of a diagnostic pattern output bus 254 connects the Q-output of each flip-flop 75 to diagnostic pattern output 227.

In operation of diagnostic information collector 260, each XOR gate 71 receives at its inputs a respective bit (e.g., bit OP₁) of the output pattern and the corresponding bit (e.g., bit EP₁) of the corresponding expected pattern. Typically, each bit of the output pattern is identical to the corresponding bit of the corresponding expected pattern so that the output of each XOR gate 71 is in a logical 0 state. OR gate 250 receives the outputs of the XOR gates each in a logical 0 state and, in response, outputs the fault indication signal in a logical 0 state that provides no fault indication.

After each read operation performed by memory circuit 14, the difference pattern collectively provided at the outputs of XOR gates 71 is clocked into the respective flip-flops 75 constituting buffer 264. The Q-outputs of the flip-flops and, later, the difference pattern output as a diagnostic pattern at diagnostic pattern output 227, then match the states of the outputs of XOR gates 71.

A difference between any bit of the output pattern and the corresponding bit of the corresponding expected pattern sets the output of the respective XOR gate to a logical 1 state.

The output of any one or more of XOR gates 71 in the logical 1 state causes OR gate 250 to output the fault indication signal in a logical 1 state that provides fault indication FI. Fault indication FI causes BIST controller 226 to stop BIST 216 from performing further write and read operations on memory circuit 14 once the output states of the XOR gates 71 have been clocked into flip-flops 75.

Fault indication FI additionally causes ATE 212 to receive the diagnostic pattern from diagnostic pattern output 227. Once ATE 212 has received the diagnostic pattern, it indicates this to BIST controller 226 via control path 37 (FIG. 3) and BIST controller 226 causes BIST 216 to resume its normal testing operations.

In the example shown in FIG. 6A, BIST 216 immediately stops its normal testing operations in response to fault indication FI. Accordingly, buffer 264 needs to store only a single diagnostic pattern in this example. In embodiments in which BIST 216 does not immediately stop its normal testing operations in response to fault indication FI, buffer 264 can be modified to store more than one diagnostic pattern.

FIG. 6B is a block diagram showing an exemplary channel of diagnostic information collector 260 in which buffer 264 is composed of one or more additional flip-flops 76, each similar to flip-flop 75, connected in series between the output of XOR gate 71 and the D-input of flip-flop 75. Flip-flops 76 are connected in series by connecting the D-input of each flip-flop to the Q-output of the preceding flip-flop. The remaining channels of diagnostic information collector 260 are similarly modified. In the example shown, two additional flip-flops 76 are connected in series between the output of XOR gate 71 and the D-input of flip-flop 75. Buffer 264 stores three diagnostic patterns in this example. Buffer 264 can be structured to store more or fewer diagnostic patterns in accordance with the number of additional flip-flops 76 in each channel.

When the difference patterns stored in buffer 264 are output in response to fault indication FI, the oldest diagnostic pattern is initially present at diagnostic pattern output 227. BIST controller 226 then clocks flip-flops 75 and 76 to output the next-oldest diagnostic pattern and repeats this process until all of the diagnostic patterns stored in buffer 264 have been output at diagnostic pattern output 227. Alternatively, fewer than all of the stored diagnostic patterns need be output. In an example in which BIST 216 executes one additional test cycle before it stops in response to fault indication FI, one additional flip-flop 76 is interposed between the output of XOR gate 71 and flip-flop 75, and BIST controller 226 need perform no additional clocking operations because the fault-indicating diagnostic pattern is the oldest diagnostic pattern stored in flip-flop 75.

In the example shown in FIG. 6A, buffer 264 stores the difference pattern collectively generated by XOR gates 71 as a diagnostic pattern. In embodiments in which the output pattern is stored as the diagnostic pattern, each flip-flop 75 constituting buffer 264 is connected to receive the output pattern instead of the difference pattern at its D-input. FIG. 6C is a block diagram showing an exemplary channel of diagnostic information collector 260 in which the D-input of flip-flop 75 is connected to a respective conductor (not shown) of output pattern bus 253 to receive a respective bit of the output pattern. In this example, the D-inputs of the remaining flip-flops (not shown) constituting buffer 264 are connected to respective channels (not shown) of output pattern bus 253.

In another embodiment of diagnostic information collector 260, buffer 264 is configured to store more than one output pattern by interposing additional series-connected flip-flops between the respective conductor (not shown) of output pattern bus 253 and the D-input of flip-flop 75 in a manner similar to that described above with reference to FIG. 6B.

In the above-described examples, diagnostic pattern output 227 is a multi-channel output having one channel per bit of the stored diagnostic pattern. Since it is often desirable to minimize the number of communication channels between memory device 210 and ATE 212, a multiplexer (not shown) can be interposed between diagnostic pattern output bus 254 and the diagnostic pattern output 227 of memory device 210. The multiplexer has parallel inputs connected to respective conductors (not shown) of diagnostic pattern output bus 254 and a single output that provides diagnostic pattern output 227. The multiplexer receives the bits of the diagnostic pattern in parallel via diagnostic pattern output bus 254 and outputs the diagnostic pattern as a serial bit stream at diagnostic pattern output 227. ATE 212 typically incorporates a corresponding demultiplexer (not shown) connected to diagnostic pattern input 229. Alternatively, ATE 212 lacks such demultiplexer and instead handles the diagnostic patterns received at diagnostic pattern input 229 as a serial bit stream.

Alternatively, the buffer of diagnostic information collector 220 may be structured to output the stored diagnostic patterns as a serial bit stream. FIG. 7 is a block diagram showing an example of a diagnostic information collector 270 that may be used as diagnostic information collector 220 described above with reference to FIG. 3. Diagnostic information collector 270 is composed of comparator 252 and buffer 274. Comparator 252 is described above with reference to FIG. 5. Buffer 274 is similar in structure to buffer 264 described above with reference to FIG. 6A, but differs in that, in each channel CH₁−CH_{N}, a two-input controlled switch 77 is interposed between the output of XOR gate 71 and the D-input of the flip-flop 75. The other input of controlled switch 77 is connected to the Q-output of the flip-flop 75 in the next-higher channel. For example, the other input of switch 77 in channel CH1 is connected to the Q-output of the flip-flop 75 in channel CH₂. Controlled switch 77 additionally has a control input connected to the control port 232 of diagnostic information collector 270 from which it receives a switch control signal SC from the control port 231 of BIST controller 226.

The Q-output of the flip-flop 75 of channel CH₁ only provides the diagnostic pattern output 227 of diagnostic information collector 270 and is connected to diagnostic pattern path 228. The other input of the controlled switch 77 of channel CH_{N} that, in channels CH₁−CH_{N-1}, would be connected to the Q-output of flip-flop 75 in channels CH₂−CH_{N}, respectively, is connected to a logical 0 state. Alternatively, these connections may be interchanged so that the Q-output of the flip-flop 75 of channel CH_{N} only provides the diagnostic pattern output 227 of diagnostic information collector 270 and the other input of the controlled switch 77 of channel CH₁ is connected to a logical 0 state.

During operation of diagnostic information collector 270, BIST controller 226 provides switch control signal SC in a state that sets each controlled switch 77 to connect the D-input of flip-flop 75 to the output of XOR gate 71 in the same channel. In this state, diagnostic information collector 270 operates in a manner substantially similar to that of diagnostic information collector 260 described above with reference to FIG. 6A. Specifically, buffer 274 stores the difference pattern generated by XOR gates 71 in response the most-recently read output pattern and its corresponding expected pattern as a respective diagnostic pattern.

When comparator 253 detects a difference between an output pattern received at output pattern input 239 and the corresponding expected pattern received at expected pattern input 237, it provides fault indication FI. Fault indication FI inhibits further clocking of flip-flops 75 after the most-recently generated diagnostic pattern has been stored in buffer 274 so that buffer 274 stores the most-recently generated diagnostic pattern. The most-recently generated diagnostic pattern stored in buffer 274 is the difference pattern that caused comparator 253 to provide fault indication FI. In response to fault indication FI, BIST controller 226 instructs BIST 216 to suspend its normal testing operations and changes switch control signal SC to a state that sets the controlled switches 77 in channels CH₁−CH_{N-1} to a state in which they connect the D-input of the flip-flops 75 in channels CH₁−CH_{N-1} to the Q-output of the flip-flops 75 in channels CH₂−CH_{N}, respectively, and sets the controlled switch 77 in channel CH_{N} to a state in which it connects the D-input of flip-flop 75 in channel CH_{N} to a logical 0 state, as described above. In this state, controlled switches 77 collectively connect flip-flops 75 in series to form an N-stage shift register having an output connected to diagnostic pattern path 228. BIST controller 226 then provides a sequence of N clock pulses to flip-flops 75 to cause them to shift the diagnostic pattern stored therein towards diagnostic pattern output 227 one bit at a time. The diagnostic pattern is output from diagnostic pattern output 227 as a serial bit stream. Again, ATE 212 incorporates a corresponding demultiplexer (not shown) connected to diagnostic pattern input 229 or, more typically, handles the diagnostic pattern received at diagnostic pattern input 229 as a serial bit stream. The N clock pulses additionally shift logical 0s into the N-stage shift register. This resets the shift register, so that the Q-output of each flip-flop 75 is set to a logical 0. BIST controller 226 then restores switch control signal SC to its original state, which causes controlled switches 77 to return buffer 274 to its original configuration with the Q-outputs of all the flip-flops 75 set to logical 0.

In another embodiment of diagnostic information collector 270, buffer 274 is structured to store multiple difference patterns as respective diagnostic patterns and to output such diagnostic patterns as a serial bit stream by connecting one or more additional flip-flops in series with each flip-flop 75 in a manner similar to that described above with reference to FIG. 6B. In this embodiment, switch control signal SC causes controlled switches 77 to connect flip flops 75 and the additional flip-flops to form an nN-stage shift register, where n is the total number of series-connected flip-flops in each channel. nN clock pulses are input to the flip-flops to read and reset such nN-stage shift register.

In another embodiment of diagnostic information collector 270, buffer 274 stores the output pattern as the diagnostic pattern. In such embodiment, one input of each controlled switch 77 is connected to the corresponding conductor (not shown) of output pattern bus 253 in a manner similar to that described above with reference to FIG. 6C. In yet another embodiment, buffer 274 is structured to store more than one output pattern as respective diagnostic patterns and to output such diagnostic patterns as a serial bit stream by incorporating a modification similar to that described above with reference to FIG. 6B in addition to a modification similar to that described above with reference to FIG. 6C.

In embodiments of diagnostic information collector 220 in which the temporarily-stored diagnostic patterns each include a respective address, buffer 264 described above with reference to FIGS. 6A-6C and buffer 274 described above with reference to FIG. 7 are modified to incorporate additional channels for storing the address that constitutes part of each stored diagnostic pattern. Each address-storing channel of the buffer is similar to the example of the channel shown. However, since the address is not subject to error checking, comparator 242 of such embodiments remains an N-channel device, where N is the number of bits in each output pattern.

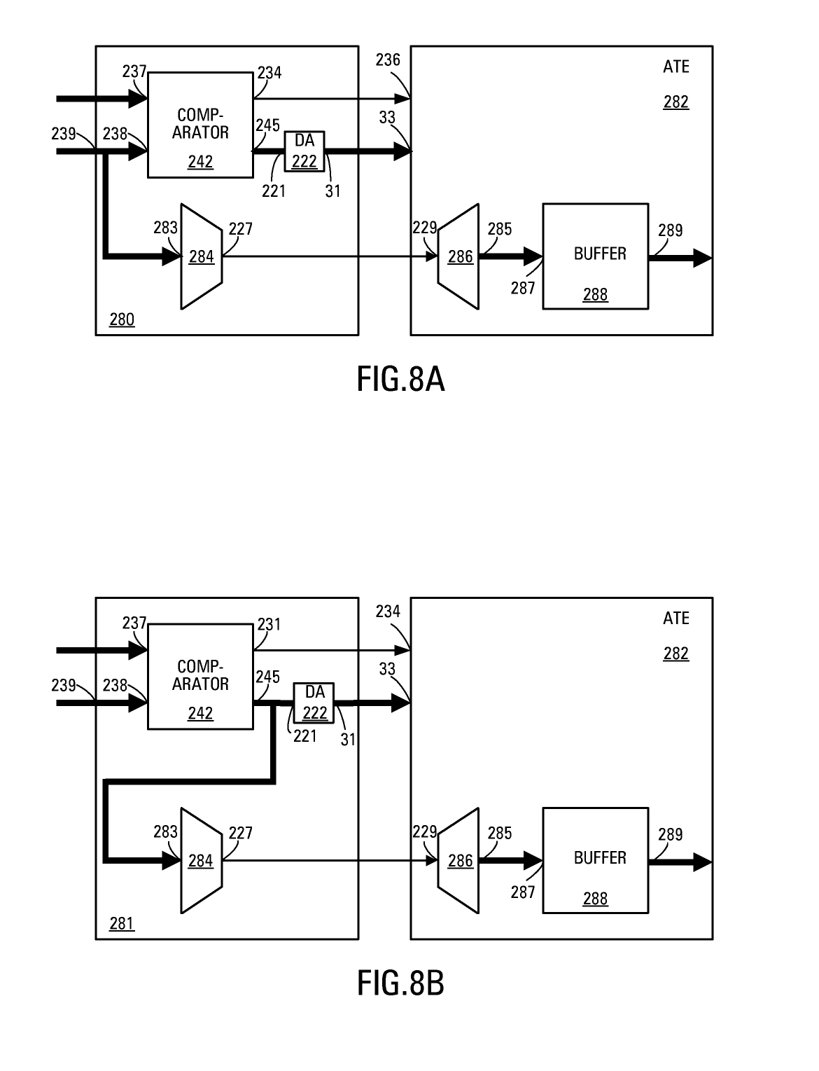

In the above examples, at least one diagnostic pattern is stored in a buffer located in memory device 210. However, the diagnostic patterns may alternatively be stored in the ATE. FIGS. 8A and 8B are block diagrams showing examples of a diagnostic information collector 280 and a diagnostic information collector 281, respectively, that may be used as diagnostic information collector 220 in memory device 210 described above with reference to FIG. 3. FIGS. 8A and 8B additionally show an example of an ATE 282 that may be used as ATE 212 in system 200 described above with reference to FIG. 3.

Diagnostic information collector 280 provides the output patterns read from memory circuit 14 as respective diagnostic patterns, and is composed of comparator 242 and an optional difference accumulator 222, both described above with reference to FIG. 4A, and is additionally composed of a multiplexer 284. Comparator 242 has an input that provides the expected pattern input 237 of diagnostic information collector 280, an output pattern input 238, an output that provides the fault indication output 234 of diagnostic information collector 280 and a difference pattern output 245. Output pattern input 238 is connected to the output pattern input 239 of diagnostic information collector 280. Optional difference accumulator 222 has a difference pattern input 221 and a test result output that provides the test result output 31 of diagnostic information collector 280. Difference pattern input 221 is connected to the difference pattern output 245 of comparator 242. Multiplexer 284 has a parallel input 283 and a serial output that provides the diagnostic pattern output 227 of diagnostic information collector 280. Parallel input 283 is connected to the output pattern input 239 of diagnostic information collector 280. Multiplexer 284 converts each output pattern it receives at parallel input 283 to a serial bit stream that it outputs at diagnostic pattern output 227.

Diagnostic information collector 281 is similar in structure and operation to diagnostic information collector 280, except that the parallel input 283 of multiplexer 284 is connected to the difference pattern output 245 of comparator 242 instead of to the output pattern input 239. Multiplexer 284 converts each difference pattern it receives at parallel input 283 to a serial bit stream that it outputs at diagnostic pattern output 227.

In embodiments of system 200 in which diagnostic information collector 280 or diagnostic information collector 281 is used as diagnostic information collector 220, ATE 282 comprises a demultiplexer 286 and a buffer 288. Demultiplexer 286 has a serial input that provides the diagnostic pattern input 229 of ATE 282, and a parallel output 285. Buffer 288 has a parallel input 287 and a diagnostic pattern output 289. Parallel input 287 is connected to the parallel output 285 of demultiplexer 286. In response to the fault indication FI received at fault indication input 233, buffer 288 outputs via diagnostic pattern output 289 at least some of the diagnostic patterns stored therein to other parts (not shown) of ATE 282 for analysis and/or storage. Alternatively, a buffer capable of storing a serial bit stream may be used as buffer 288. In such an embodiment, demultiplexer 286 is omitted.

ATE 282 operates deterministically with respect to the diagnostic patterns received at diagnostic pattern input 229, i.e., in each test cycle, ATE receives at diagnostic pattern input 229 a serial bitstream representing a respective diagnostic pattern, demultiplexes the serial bitstream and stores the resulting diagnostic pattern in buffer 288 such that diagnostic patterns corresponding to no more than a most-recently read subset of output patterns are stored. The most-recently read subset consists of the output patterns read from fewer than all of the memory locations in memory device 210.

As in the above-described embodiments of ATE 212, ATE 282 operates non-deterministically with respect to fault indication FI. Fault indication FI, which can be provided at any point in the process of testing memory device under test 210, causes BIST 216 to suspend its normal testing operations, as described above, and additionally causes ATE 282 to perform an operation in which it outputs at least some of the diagnostic patterns stored in buffer 288 to other parts (not shown) of ATE 282 for analysis and/or storage. Once the diagnostic patterns are output from buffer 288, ATE 282 instructs BIST 216 via BIST controller 226 to resume its normal testing operations. The minimum number of diagnostic patterns that need be stored in buffer 288 and, hence, the minimum size of buffer 288, depends on the maximum number of output patterns BIST 216 reads from memory circuit 14 before it can suspend its normal testing operations in response to fault indication FI.

In embodiments of diagnostic information collector 220 in which the temporarily-stored diagnostic patterns each include a respective address, diagnostic information collector 280 described above with reference to FIG. 8A and diagnostic information collector 281 described above with reference to FIG. 8B may be modified to increase the width of multiplexer 284, demultiplexer 286 and buffer 288 to accommodate the address that constitutes part of each stored diagnostic pattern. The additional inputs of multiplexer 286 are connected to the output of address generator 24.

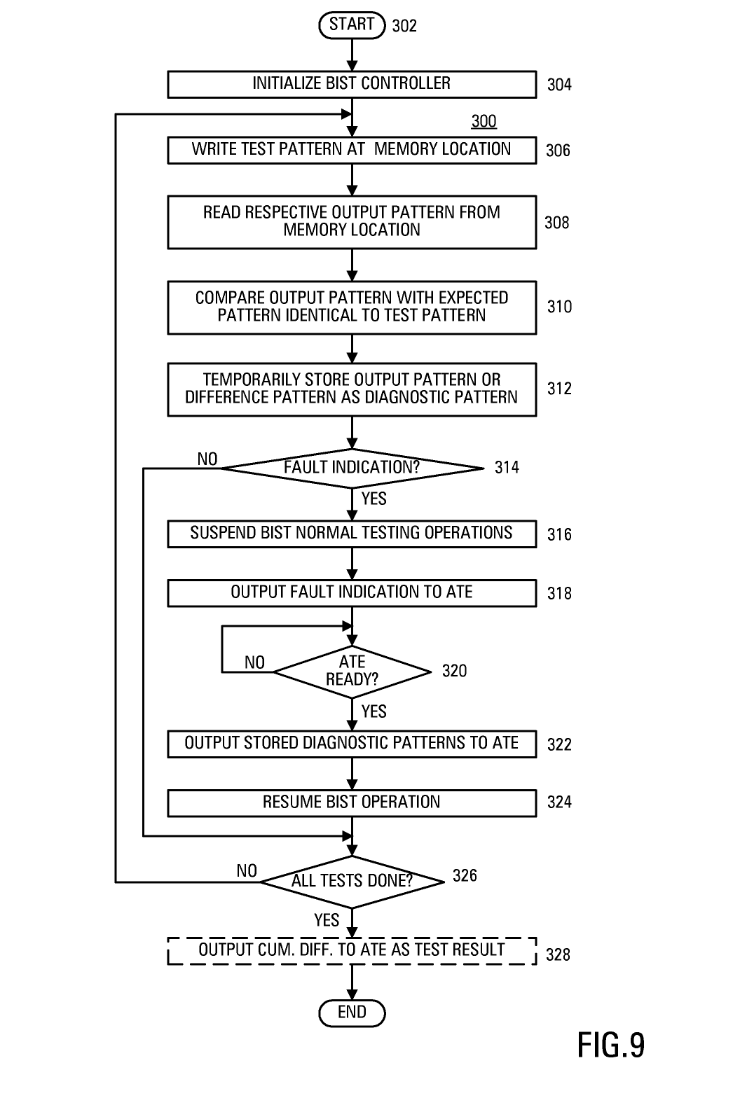

FIG. 9 is a flow chart showing an example of a method 300 in accordance with an embodiment of the invention for obtaining diagnostic information from memory device 210 having a built-in self-test system. In this embodiment, BIST 216 suspends its normal testing operations from the time that it receives fault indication FI until the diagnostic patterns have been output to the ATE. This mode of operation minimizes the size requirements of buffer 244.

Execution begins at block 302. In block 304, BIST controller 226 is initialized. In block 306, a test pattern is written at a memory location in memory circuit 14. In block 308, a respective output pattern is read from the memory location in memory circuit 14. In block 310, the output pattern read from the memory location is compared with the corresponding expected pattern, i.e., a pattern identical to the test pattern that was written at the memory location in block 306. In block 312, a diagnostic pattern corresponding to the output pattern read in block 308 is temporarily stored. The diagnostic pattern corresponding to the output pattern read in block 308 is the output pattern itself or a difference pattern representing the difference between the output pattern read from the memory location in block 308 and the corresponding expected pattern. The diagnostic pattern may additionally comprise the address of the memory location from which the output pattern was read, as described above.

In block 314, a test is performed to determine whether the comparison performed in block 310 has provided a fault indication FI. A NO result causes execution to advance to block 326, which will be described below. A YES result causes execution to advance to block 316, where BIST 216 suspends its normal testing operations.

In block 318, fault indication FI is output to ATE 212. Fault indication FI indicates to ATE 212 that diagnostic patterns usable as diagnostic information are ready for output to the ATE.

In block 320, a test is performed to determine whether ATE 212 is ready to receive the stored diagnostic patterns. A NO result causes execution to return to block 320, typically via a delay (not shown). A YES result causes execution to advance to block 322.

In block 322, at least some of the temporarily stored diagnostic patterns are output to ATE 212.

Once the diagnostic pattern output process performed in block 322 is complete, execution advances to block 324, where BIST 216 resumes its normal testing operations.

Execution advances to block 326 directly from block 324 or as the result of a NO result in block 314. In block 326, a test is performed to determine whether BIST 216 has performed all the tests in the test sequence. A NO result in block 326 causes execution to return to block 306, where execution of the next test in the test sequence begins. A YES result in block 326 causes execution to advance to block 328.

In optional block 328, a test result for memory device under test 210 is output. Testing of memory device under test 210 then ends. Block 328 may be omitted in embodiments of method 300 performed using an embodiment of ATE 212 that can determine a test result for the memory device under test instead of receiving a test result from the memory device under test.

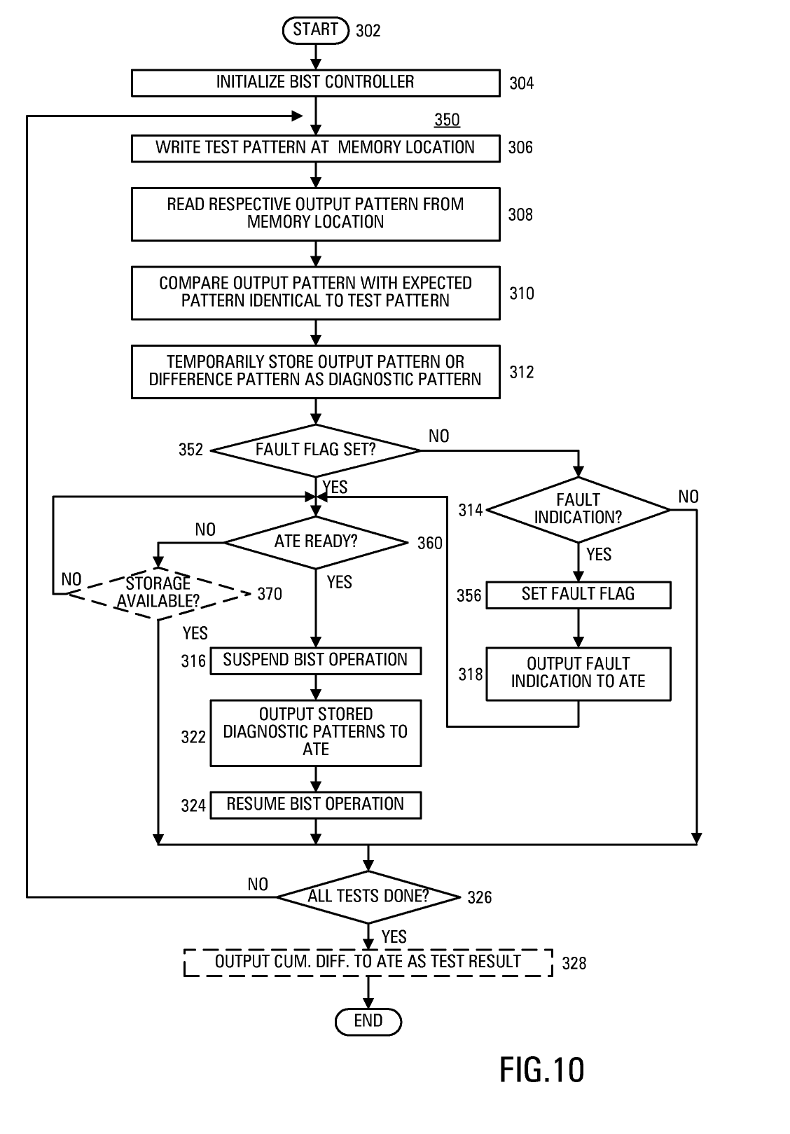

FIG. 10 is a flow chart showing an example of a method 350 in accordance with an embodiment of the invention for obtaining diagnostic information from memory device 210 having a built-in self-test system. In this embodiment, BIST 216 continues to perform normal testing operations on memory device 210 until ATE 212 indicates that it is ready to receive the stored diagnostic patterns. Once ATE 212 indicates that it is ready to receive the stored diagnostic patterns, BIST 216 suspends normal testing operations while the stored diagnostic patterns are output to the ATE.

Blocks 302, 304, 306, 308, 310 and 312 are executed as described above with reference to FIG. 9. These blocks will not be described again here. Once the diagnostic pattern has been temporarily stored in block 312, execution advances to block 352.

In block 352, a test is performed to determine whether a fault flag has been set. The fault flag being set indicates that, in a previous test cycle, the comparison performed in block 310 provided fault indication FI, but ATE 212 has not yet indicated its readiness to receive the stored diagnostic patterns. A NO result (no fault flag set) causes execution to advance to block 314, described next. A YES result causes execution to advance to block 360, which will be described below.

In block 314, a test is performed to determine whether the comparison performed in block 310 provided fault indication FI. A NO result causes execution to advance to block 326, which will be described below. A YES result causes execution to advance to block 356, which will be described next.

In block 356, the fault flag is set, and execution advances to block 318.

In block 318, fault indication FI is output to ATE 212. Fault indication FI indicates to ATE 212 that diagnostic patterns usable as diagnostic information are ready for output to the ATE. Execution then advances to block 360, which will be described next.

A YES result in block 352 (fault flag set) or execution of block 318 causes execution to advance to block 360. In block 360, a test is performed to determine whether ATE 212 is ready to receive the stored diagnostic patterns. A YES result in block 360 causes execution to advance to block 316, which will be described below. In one embodiment of method 350, a NO result in block 360 causes execution to advance directly to block 326, which will be described below. In the example of method 350 shown in FIG. 10, a NO result in block 360 causes execution to advance to block 326 via optional block 370.

In block 370, a test is performed to determine whether storage is available to store an additional diagnostic pattern. In an example, a test is performed to determine whether storing such additional diagnostic pattern would overwrite the diagnostic pattern stored in block 310 when the comparison performed in block 312 provided fault indication FI. A YES result causes execution to advance to block 326, which will be described below. A NO result in block 370 causes execution to return to block 360, typically via a delay (not shown). This prevents an additional diagnostic pattern from being stored until storage is available.

Execution advances to block 316 as the result of a YES result in block 360. In block 316, BIST 216 suspends its normal testing operations.

In block 322, at least some of the stored diagnostic patterns are output to ATE 212.

Once the diagnostic pattern output process performed in block 322 is complete, execution advances to block 324, where BIST 216 resumes its normal testing operations. Execution then advances to block 326, which will be described next.

Execution advances to block 326 from block 324, as the result of a NO result in block 314 or as the result of a YES result in block 370. In block 326, a test is performed to determine whether BIST 216 has performed all the tests in the test sequence. A NO result causes execution to return to block 306, where execution of the next test is begun. A YES result causes execution to advance to block 328.

In optional block 328, a test result for memory device under test 210 is output. Testing of memory device under test 210 then ends. Block 328 may be omitted in embodiments of method 300 performed using an embodiment of ATE 212 that can determine a test result for the memory device under test instead receiving a test result from the memory device under test.

This disclosure describes the invention in detail using illustrative embodiments. However, the invention defined by the appended claims is not limited to the precise embodiments described.

We claim:

1. A method of obtaining diagnostic information from a memory device comprising a built-in self-test system (BIST), the method comprising:
using the BIST to write a test pattern at a memory location in the memory device and to read a respective output pattern from the memory location;
comparing the output pattern read from the memory location with a corresponding expected pattern identical to the test pattern, the comparing providing a fault indication when the output pattern differs from the expected pattern;
temporarily storing a diagnostic pattern corresponding to the output pattern such that diagnostic patterns corresponding to no more than a most-recently read subset of output patterns are stored, the most-recently read subset consisting of output patterns read from fewer than all memory locations in the memory device; and
outputting at least some of the stored diagnostic patterns in response to the comparing providing the fault indication.

2. The method of claim 1, in which the storing comprises storing the output pattern as the diagnostic pattern.

3. The method of claim 1, in which the storing comprises storing a difference pattern representing a difference between the output pattern and the expected pattern as the diagnostic pattern.

4. The method of claim 1, additionally comprising suspending operation of the BIST in response to the fault indication.

5. The method of claim 1, additionally comprising suspending operation of the BIST during the outputting.

6. The method of claim 1, in which:
the method additionally comprises connecting the memory device to automatic test equipment; and
the outputting comprises outputting the at least some of the stored diagnostic patterns to the automatic test equipment.

7. The method of claim 6, in which the outputting additionally comprises:
providing the fault indication to the automatic test equipment;
in response to the fault indication, awaiting an indication from the automatic test equipment that the automatic test information is ready to receive the stored diagnostic patterns, and on receipt of the indication, outputting the at least some of the stored diagnostic patterns to the automatic test equipment.

8. The method of claim 6, additionally comprising storing the diagnostic patterns received from the device under test in the automatic test equipment.

9. The method of claim 1, additionally comprising outputting location information indicating a faulty memory location.

10. The method of claim 9, in which:
the diagnostic patterns each additionally comprise a respective address; and
the address constitutes the location information.

11. A device, comprising:
a memory circuit;
a built-in self-test system (BIST) operable to write a test pattern at a memory location in the memory circuit and to read a respective output pattern from the memory location;
a comparator operable in real time to compare the output pattern with a corresponding expected pattern identical to the test pattern and to provide a fault indication when the output pattern differs from the expected pattern; and
a buffer operable to store temporarily a diagnostic pattern corresponding to the output pattern such that diagnostic patterns corresponding to no more than a most-recently read subset of output patterns are stored, the most-recently stored subset of output patterns consisting of output patterns read from fewer than all memory locations in the memory device, the buffer additionally operable in response to the fault indication to output at least some of the stored diagnostic patterns.

12. The device of claim 11, in which the buffer stores the output pattern read from the memory location as the diagnostic pattern.

13. The device of claim 11, in which the buffer stores a difference pattern as the diagnostic pattern, the difference pattern representing a difference between the output pattern read from the memory location and the expected pattern.

14. The device of claim 11, in which the fault indication additionally causes the BIST to suspend normal testing operation.

15. The device of claim 11, the BIST suspends normal testing operation while the buffer outputs the stored diagnostic patterns.

16. A system, comprising:
automatic test equipment; and
a memory device connected to the automatic test equipment, the memory device comprising:
a memory circuit,
a built-in self-test system (BIST) operable to write a test pattern at a memory location in the memory circuit and to read a respective output pattern from the memory location,
a comparator operable in real time to compare the output pattern with a corresponding expected pattern identical to the test pattern and to provide a fault indication when the output pattern differs from the expected pattern, and
a buffer operable to store temporarily a diagnostic pattern corresponding to the output pattern such that diagnostic patterns corresponding to no more than a most-recently read subset of output patterns are stored, the most-recently stored subset of output patterns consisting of output patterns read from fewer than all memory locations in the memory device, the buffer additionally operable in response to the fault indication to output at least some of the stored diagnostic patterns to the automatic test equipment.

17. The system of claim 16, in which:
the fault indication is output to the automatic test equipment;
in response to the fault indication, the automatic test equipment is operable to provide to the memory device an indication that it is ready to receive the stored diagnostic patterns, and
the buffer is operable to output the at least some of the stored diagnostic patterns to the automatic test equipment on receipt of the indication from the automatic test equipment.

18. The system of claim 16, in which the automatic test equipment is operable to store the diagnostic patterns received from the device under test.

19. The system of claim 16, in which the automatic test equipment is operable to receive location information from the memory device, the location information indicating an address of a faulty memory location.

20. The system of claim 19, in which:
the diagnostic patterns output to the automatic test equipment each comprise a respective address; and
the addresses collectively constitute the location information.
